(19) United States
(12) Patent Application Publication
(10) Pub. No.: US 2026/0107565 A1
(43) Pub. Date: Apr. 16, 2026

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Tzu-Yang HO, Hsinchu (TW); Yu-Jhen JIANG, Hsinchu (TW); Kai-Chieh YANG, New Taipei (TW)

(21) Appl. No.: 19/069,383

(22) Filed: Mar. 4, 2025

Related U.S. Application Data
(60) Provisional application No. 63/706,642, filed on Oct. 12, 2024.

(51) Int. Cl. H10D 84/83; H01L 21/02; H10D 30/00; H10D 30/01; H10D 30/43; H10D 62/10; H10D 62/13; H10D 64/23; H10D 64/62; H10D 84/01

(52) U.S. Cl. CPC H10D 84/832; H10D 30/014; H10D 30/0191; H10D 30/43; H10D 30/502; H10D 62/121; H10D 62/151; H10D 64/256; H10D 64/62; H10D 84/017; H10P 14/6339

(57) ABSTRACT

Embodiments of the present disclosure provide a semiconductor device structure and methods of forming the same. The structure includes a gate electrode layer disposed over a semiconductor layer, a source/drain region disposed adjacent the semiconductor layer, an interlayer dielectric (ILD) layer disposed over the source/drain region, a conductive feature disposed in the ILD layer over the source/drain region, a first dielectric layer disposed between the gate electrode layer and the conductive feature, a second dielectric layer distinct from the first dielectric layer disposed between the first dielectric layer and the gate electrode layer, a contact etch stop layer disposed between the second dielectric layer and the gate electrode layer, and a spacer disposed between the contact etch stop layer and the gate electrode layer.

### CROSS-REFERENCE TO RELATED APPLICATIONS

This application claims priority to U.S. Provisional Application Ser. No. 63/706,642 filed Oct. 12, 2024, which is incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, 6 are perspective views of various stages of manufacturing a semiconductor device structure, in accordance with some embodiments.

FIGS. 7A, 8A, 9A, 10A, 11A, and 12A are cross-sectional side views of various stages of manufacturing the semiconductor device structure taken along line A-A of FIG. 6, in accordance with some embodiments.

FIGS. 7B, 8B, 9B, 10B, 11B, and 12B are cross-sectional side views of various stages of manufacturing the semiconductor device structure taken along line B-B of FIG. 6, in accordance with some embodiments.

FIGS. 7C, 8C, 9C, 10C, 11C, and 12C are cross-sectional side views of various stages of manufacturing the semiconductor device structure taken along line C-C of FIG. 6, in accordance with some embodiments.

FIGS. 13A, 13B, 13C, 13D, 13D-1, 13E, 13F, 13G, and 13G-1 are cross-sectional side views of various stages of manufacturing the semiconductor device structure taken along line A-A of FIG. 6, in accordance with some embodiments.

FIG. 13G-2 is a cross-sectional side view of one of various stages of manufacturing the semiconductor device structure taken along line C-C of FIG. 6, in accordance with some embodiments.

FIGS. 14A, 14B, 14C, 14D, and 14E are cross-sectional side views of various stages of manufacturing the semiconductor device structure taken along line A-A of FIG. 6, in accordance with alternative embodiments.

FIGS. 15A, 15B, 15C, and 15D are cross-sectional side views of various stages of manufacturing the semiconductor device structure taken along line A-A of FIG. 6, in accordance with alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs, such as gate all around (GAA) FETs, for example Horizontal Gate All Around (HGAA) FETs or Vertical Gate All Around (VGAA) FETs, implementations of some aspects of the present disclosure may be used in other processes and/or in other devices, such as planar FETs, Fin-FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

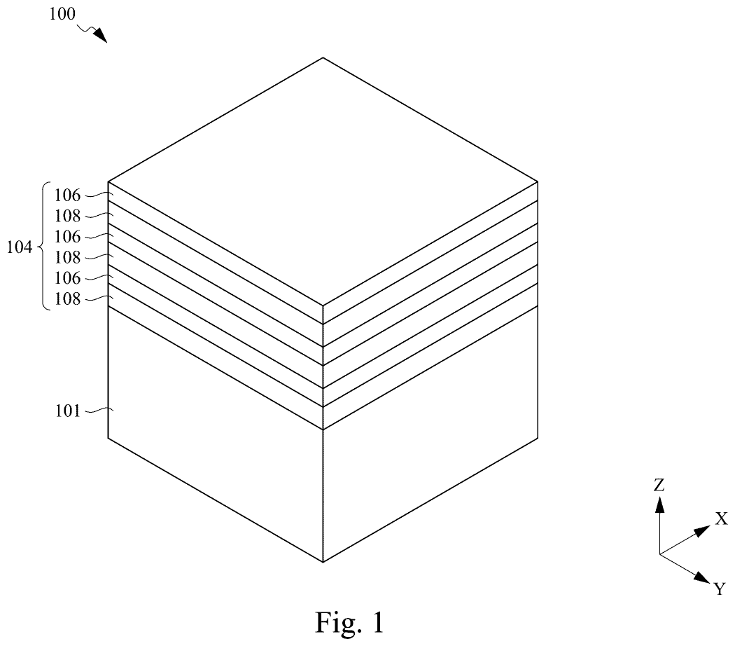

FIGS. 1-13G show exemplary processes for manufacturing a semiconductor device structure 100 according to embodiments of the present disclosure. It is understood that additional operations can be provided before, during, and after processes shown by FIGS. 1-13G, and some of the operations described below can be replaced or eliminated, for additional embodiments of the method. The order of the operations/processes is not limiting and may be interchangeable.

FIGS. 1-6 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100.

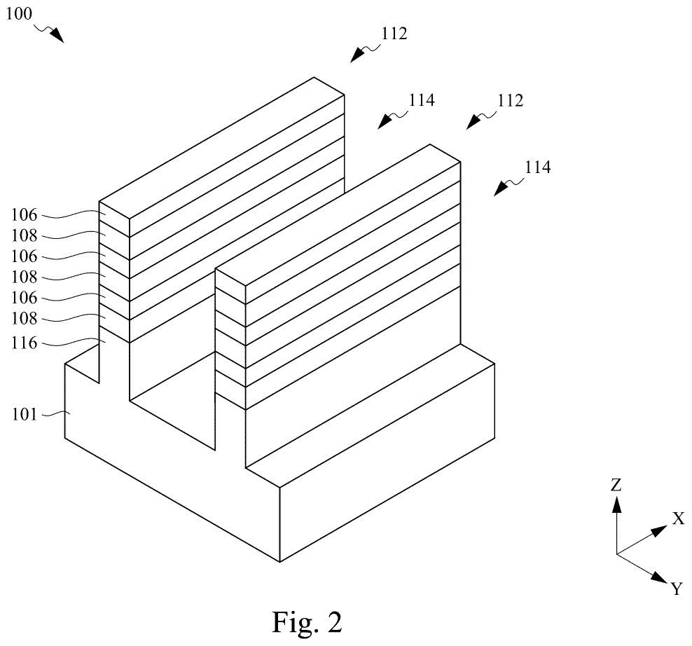

In FIG. 2, fin structures 112 are formed from the stack of semiconductor layers 104. Each fin structure 112 has an upper portion including the semiconductor layers 106, 108 and a substrate portion 116 formed from the substrate 101. The fin structures 112 may be formed by patterning a hard mask layer (not shown) formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

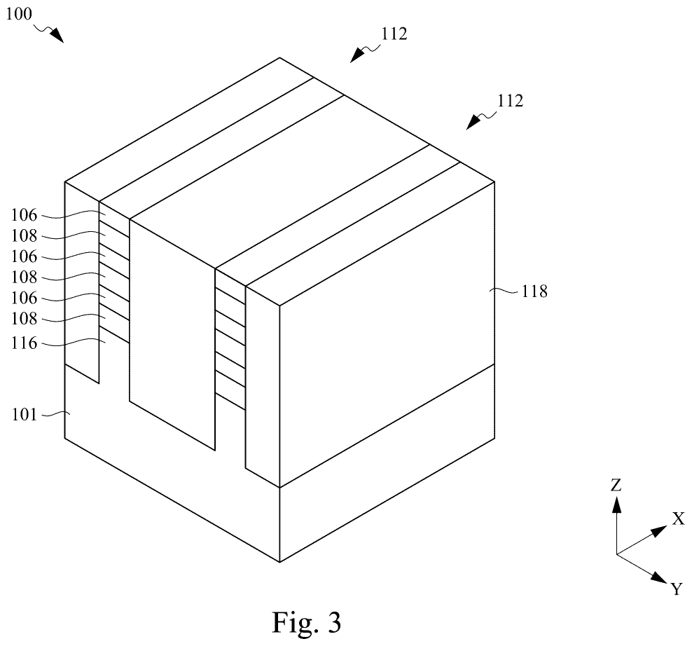

In FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

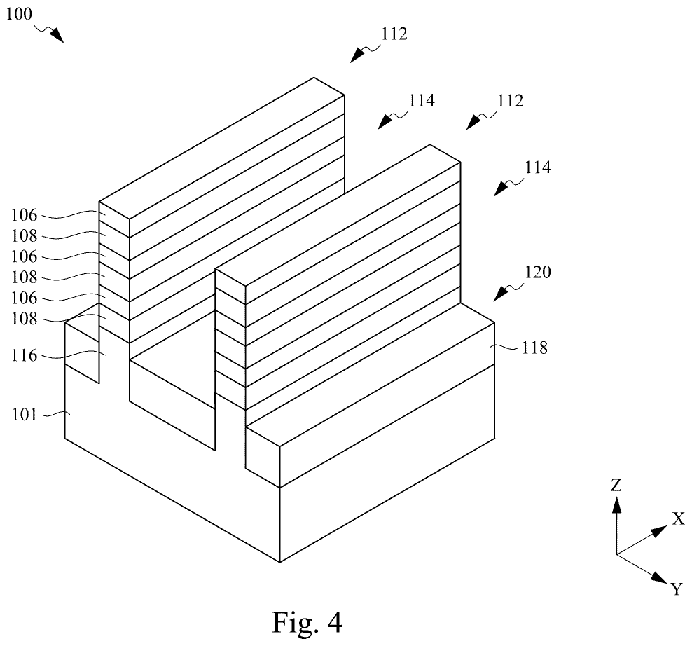

In FIG. 4, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the substrate portion 116 formed from the substrate 101.

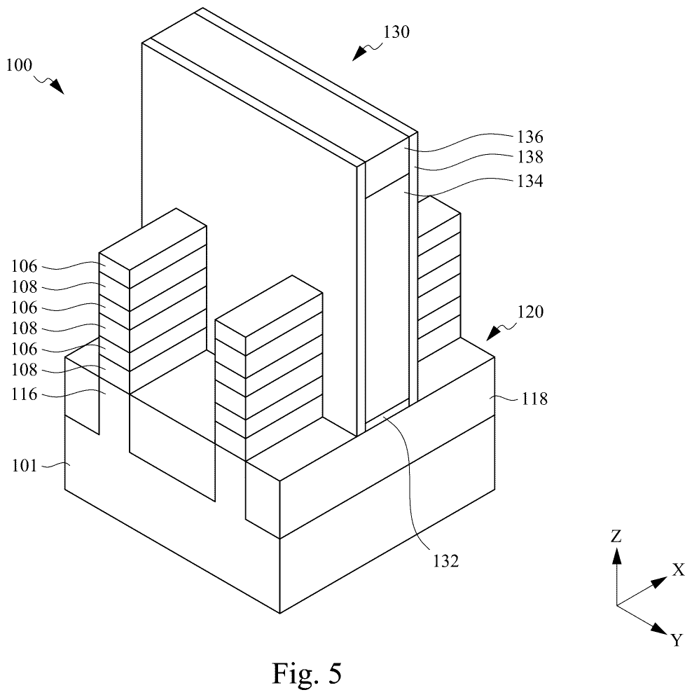

In FIG. 5, one or more sacrificial gate structures 130 (only one is shown) are formed over the semiconductor device structure 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. Spacers 138 are then formed on sidewalls of the sacrificial gate structures 130. The spacers 138 may be formed by conformally depositing one or more layers for the spacers 138 and anisotropically etching the one or more layers, for example. In some embodiments, the spacers 138 are also formed on sidewalls of the exposed portions of the fin structures 112. While one sacrificial gate structure 130 is shown, two or more sacrificial gate structures 130 may be arranged along the X direction in some embodiments. In some embodiments, a contact poly pitch (CPP), which is a minimum center-to-center distance between adjacent sacrificial gate electrode layers 134, ranges from about 35 nm to about 100 nm.

The sacrificial gate dielectric layer 132 may include one or more layers of dielectric material, such as a silicon oxide-based material. The sacrificial gate electrode layer 134 may include silicon such as polycrystalline silicon or amorphous silicon. The mask layer 136 may include more than one layer, such as an oxide layer and a nitride layer. The spacer 138 may be made of a dielectric material such as silicon oxide, silicon nitride, silicon carbide, silicon oxynitride, SiCN, silicon oxycarbide, SiOCN, and/or combinations thereof. In some embodiments, the k value of the spacer 138 may range from about 4 to about 10.

The portions of the fin structures 112 that are covered by the sacrificial gate electrode layer 134 of the sacrificial gate structure 130 serve as channel regions for the semiconductor device structure 100.

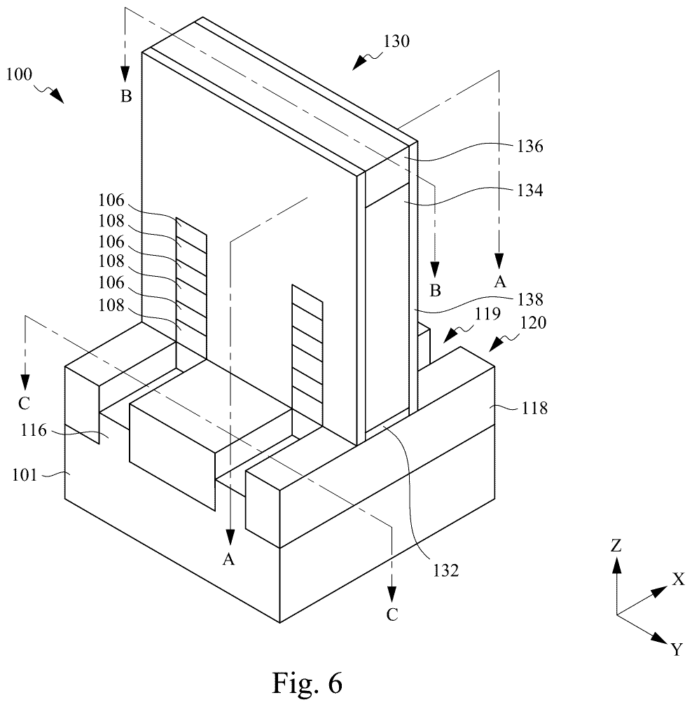

In FIG. 6, the portions of the fin structures 112 not covered by the sacrificial gate structure 130 and the spacers 138 are recessed to a level above, at, or below the top surfaces of the isolation regions 120. The recess of the portions of the fin structures 112 can be done by an etch process, either isotropic or anisotropic etch process, and the etch process may be selective with respect to one or more crystalline planes of the substrate 101. The etch process may be a dry etch, such as a RIE, NBE, or the like, or a wet etch, such as using tetramethylammonium hydroxide (TMAH), ammonium hydroxide (NH₄OH), or any suitable etchant.

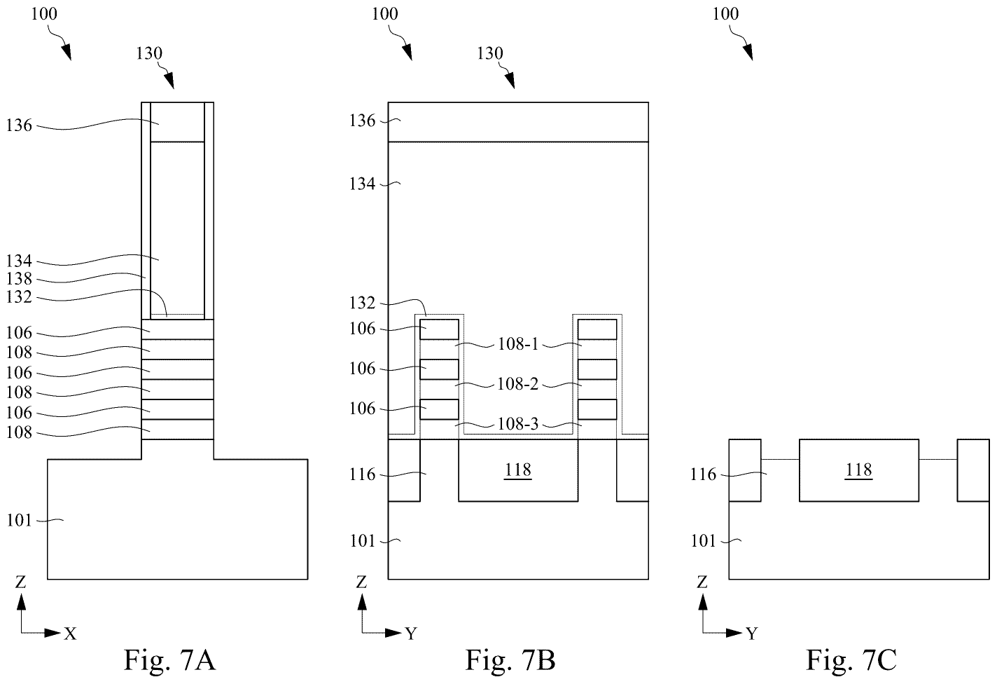

FIGS. 7A, 7B, and 7C are cross-sectional side views of the semiconductor device structure 100 taken along line A-A, line B-B, and line C-C of FIG. 6, respectively.

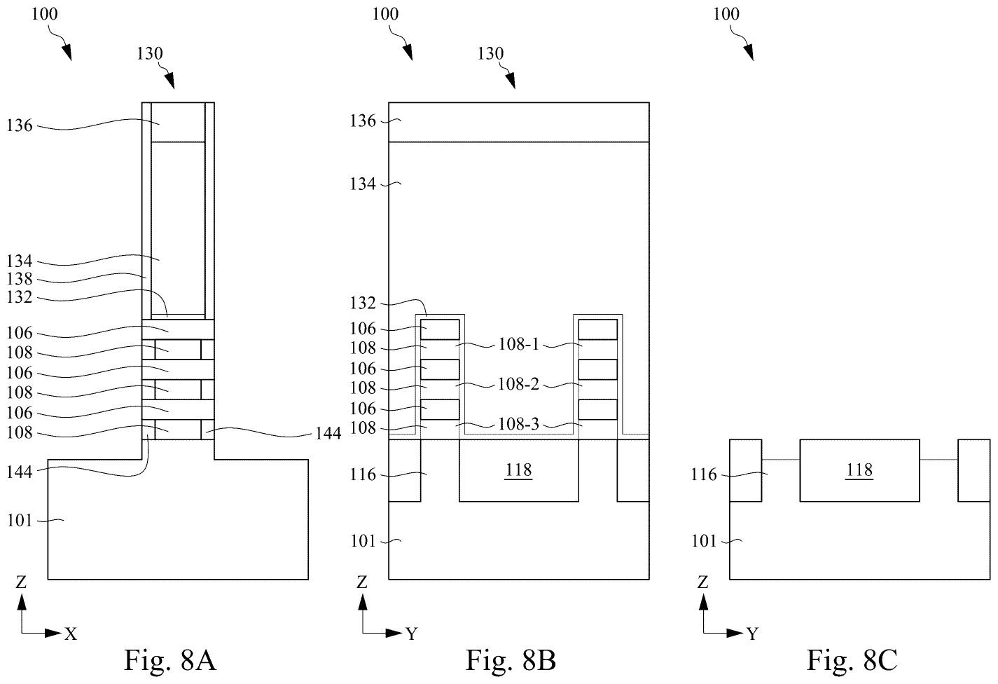

FIGS. 8A, 8B, and 8C are cross-sectional side views of one of various stages of manufacturing the semiconductor device structure 100 taken along line A-A, line B-B, and line C-C of FIG. 6, respectively, in accordance with some embodiments. As shown in FIG. 8A, edge portions of each second semiconductor layer 108 of the stack of semiconductor layers 104 are removed horizontally along the X direction. The removal of the edge portions of the second semiconductor layers 108 forms cavities. In some embodiments, the portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

After removing edge portions of each second semiconductor layers 108, a dielectric layer is deposited in the cavities to form dielectric spacers 144. The dielectric spacers 144 may be made of a low-K dielectric material, such as SiON, SiCN, SiOC, SiOCN, or SiN. In some embodiments, the k value of the dielectric spacers 144 may range from about 4 to about 10. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The remaining second semiconductor layers 108 are capped between the dielectric spacers 144 along the X direction.

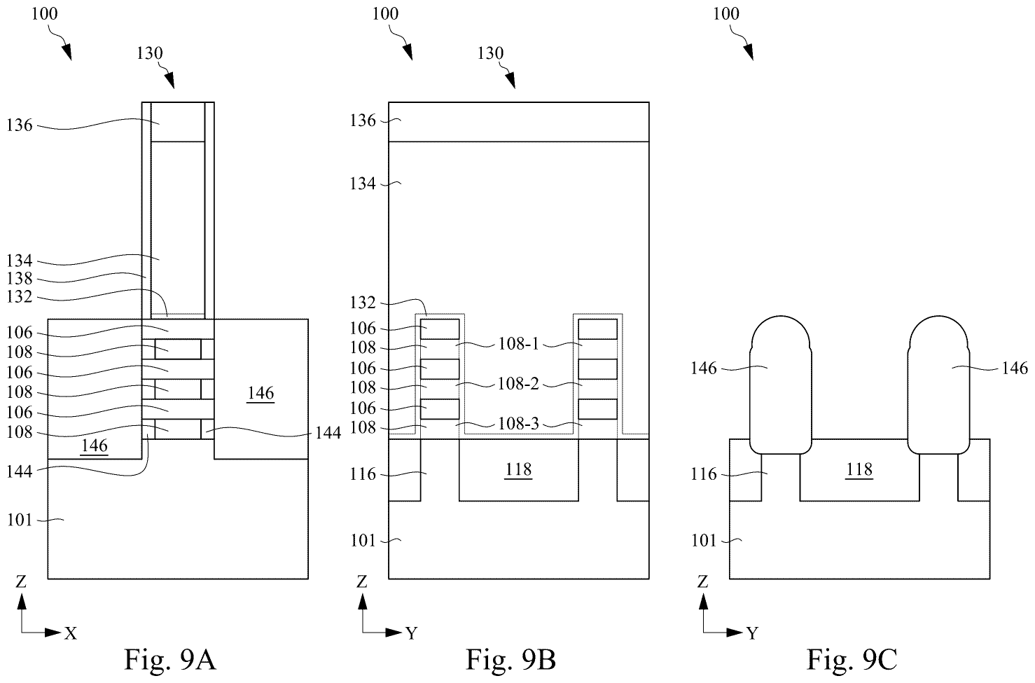

FIGS. 9A, 9B, and 9C are cross-sectional side views of one of various stages of manufacturing the semiconductor device structure 100 taken along line A-A, line B-B, and line C-C of FIG. 6, respectively, in accordance with some embodiments. As shown in FIGS. 9A and 9C, source/drain (S/D) regions 146 are formed from the substrate portion 116. The S/D regions 146 may grow both vertically and horizontally to form facets, which may correspond to crystalline planes of the material used for the substrate portion 116. In this disclosure, a source region and a drain region are interchangeably used, and the structures thereof are substantially the same. Furthermore, source/drain region(s) may refer to a source or a drain, individually or collectively dependent upon the context. The S/D regions 146 may be made of one or more layers of Si, SiP, SiC and SiCP for n-channel FETs or Si, SiGe, Ge for p-channel FETs. For p-channel FETs, p-type dopants, such as boron (B), may also be included in the S/D regions 146. The S/D regions 146 may be formed by an epitaxial growth method using CVD, ALD or MBE.

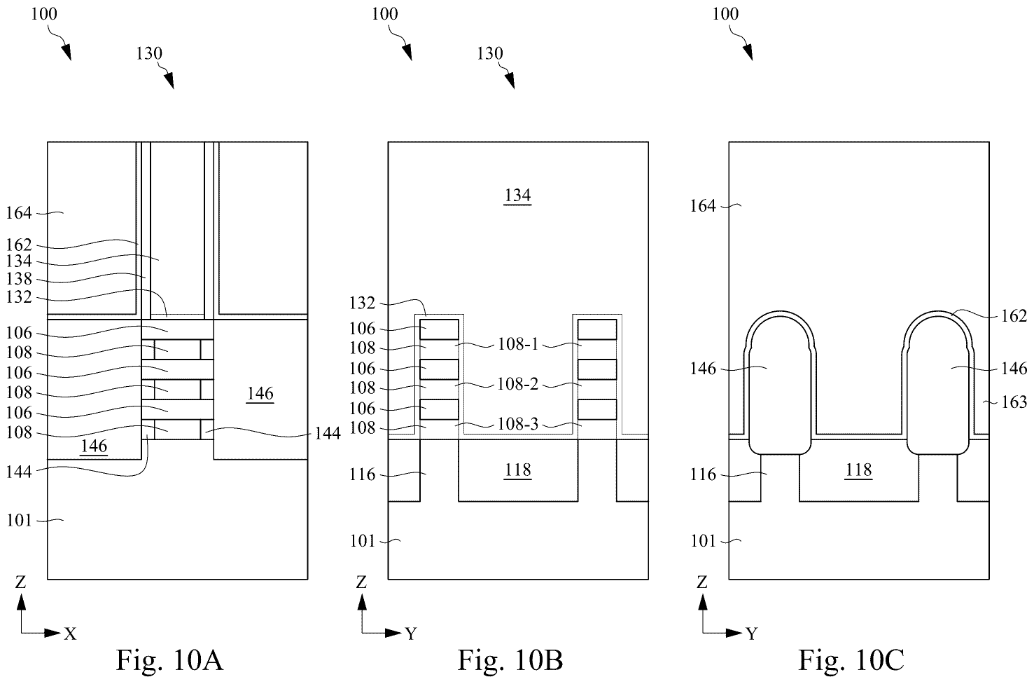

FIGS. 10A, 10B, and 10C are cross-sectional side views of one of various stages of manufacturing the semiconductor device structure 100 taken along line A-A, line B-B, and line C-C of FIG. 6, respectively, in accordance with some embodiments. In FIGS. 10A, 10B, and 10C, a contact etch stop layer (CESL) 162 is conformally formed on the exposed surfaces of the semiconductor device structure 100. The CESL 162 covers the sidewalls of the sacrificial gate structure 130, the insulating material 118, and the S/D regions 146. The CESL 162 may include a nitrogen-containing material, such as silicon nitride, and may be formed by CVD, PECVD, ALD, or any suitable deposition technique. In some embodiments, the CESL 162 has a k value ranging from about 7 to about 10. Next, an interlayer dielectric (ILD) layer 164 is formed on the CESL 162 over the semiconductor device structure 100. The materials for the ILD layer 164 may include compounds including Si, O, C, and/or H, such as silicon oxide, SiCOH, or SiOC. Organic materials, such as polymers, may also be used for the ILD layer 164. The ILD layer 164 may be deposited by a PECVD process or other suitable deposition technique. In some embodiments, the k value of the ILD layer 164 is less than 4, such as from about 2.5 to about 3.5. In some embodiments, after formation of the ILD layer 164, the semiconductor device structure 100 may be subject to a thermal process to anneal the ILD layer 164.

After the ILD layer 164 is formed, a planarization operation, such as CMP, is performed on the semiconductor device structure 100 until the sacrificial gate electrode layer 134 is exposed, as shown in FIGS. 10A and 10B.

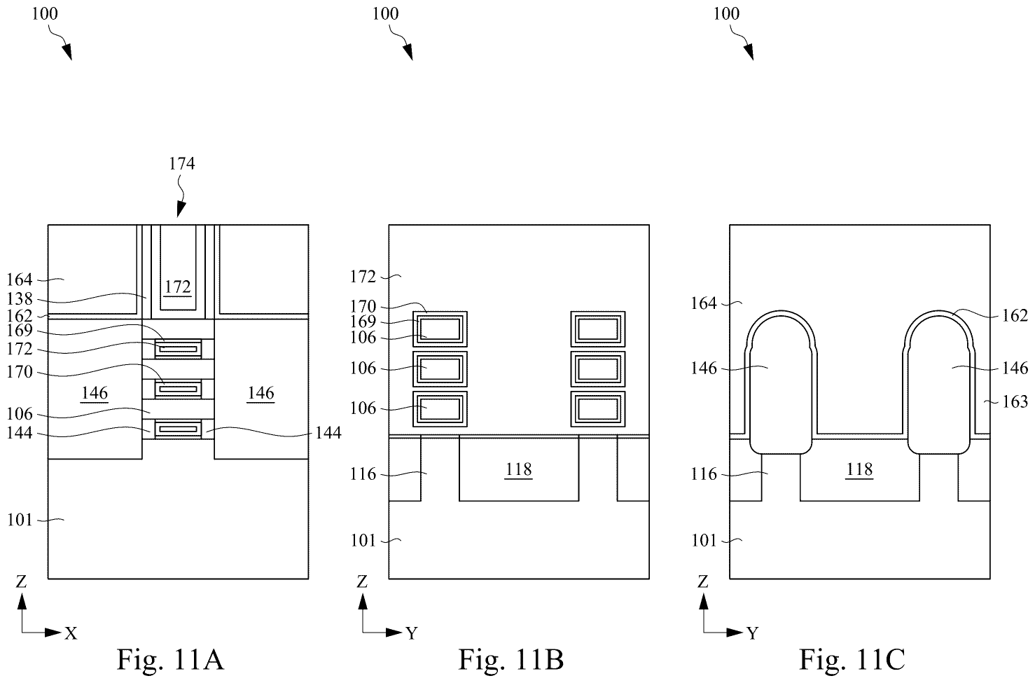

FIGS. 11A, 11B, and 11C are cross-sectional side views of one of various stages of manufacturing the semiconductor device structure 100 taken along line A-A, line B-B, and line C-C of FIG. 6, respectively, in accordance with some embodiments. As shown in FIGS. 11A and 11B, the sacrificial gate structure 130 and the second semiconductor layers 108 are removed. The removal of the sacrificial gate structure 130 and the semiconductor layers 108 forms an opening between the spacers 138 and between first semiconductor layers 106. The ILD layer 164 protects the S/D regions 146 during the removal processes. The sacrificial gate structure 130 can be removed using plasma dry etching and/or wet etching. The sacrificial gate electrode layer 134 may be first removed by any suitable process, such as dry etch, wet etch, or a combination thereof, followed by the removal of the sacrificial gate dielectric layer 132, which may also be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the spacers 138, the ILD layer 164, and the CESL 162.

The second semiconductor layers 108 may be removed using a selective wet etching process. In cases where the second semiconductor layers 108 are made of SiGe and the first semiconductor layers 106 are made of Si, the chemistry used in the selective wet etching process removes the SiGe while not substantially affecting Si, the dielectric materials of the spacers 138, and the dielectric spacers 144. In one embodiment, the second semiconductor layers 108 can be removed using a wet etchant such as, but not limited to, hydrofluoric (HF), nitric acid (HNO₃), hydrochloric acid (HCl), phosphoric acid (H₃PO₄), a dry etchant such as fluorine-based (e.g., F₂) or chlorine-based gas (e.g., Cl₂), or any suitable isotropic etchants.

After the formation of the nanostructure channels (i.e., the exposed portions of the first semiconductor layers 106), a gate dielectric layer 170 is formed to surround the exposed portions of the first semiconductor layers 106, and a gate electrode layer 172 is formed on the gate dielectric layer 170. The gate dielectric layer 170 and the gate electrode layer 172 may be collectively referred to as a gate structure 174. In some embodiments, an interfacial layer (IL) 169 is formed between the gate dielectric layer 170 and the exposed surfaces of the first semiconductor layers 106. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique. The gate electrode layer 172 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof. The gate electrode layer 172 may be formed by CVD, ALD, electro-plating, or other suitable deposition technique. The gate electrode layer 172 may be also deposited over the upper surface of the ILD layer 164. The gate dielectric layer 170 and the gate electrode layer 172 formed over the ILD layer 164 are then removed by using, for example, CMP, until the top surface of the ILD layer 164 is exposed.

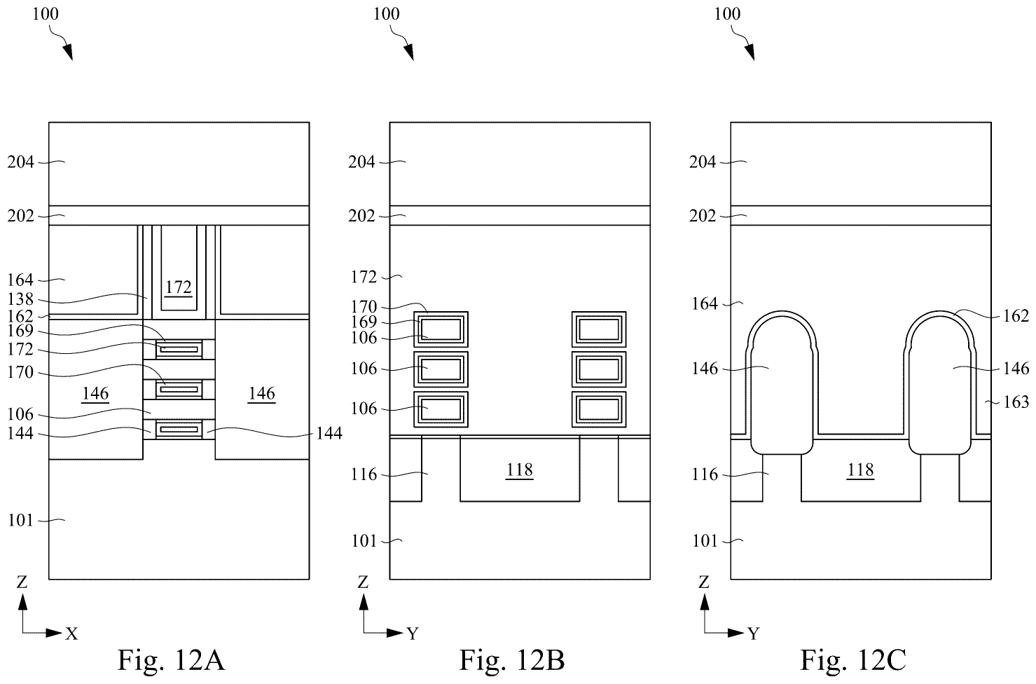

FIGS. 12A, 12B, and 12C are cross-sectional side views of one of various stages of manufacturing the semiconductor device structure 100 taken along line A-A, line B-B, and line C-C of FIG. 6, respectively, in accordance with some embodiments. As shown in FIGS. 12B and 12C, an etch stop layer 202 is formed on the ILD layer 164 and the gate structures 174, and another ILD layer 204 is formed on the etch stop layer 202. The etch stop layer 202 may include the same material as the CESL 162, and the ILD layer 204 may include the same material as the ILD layer 164.

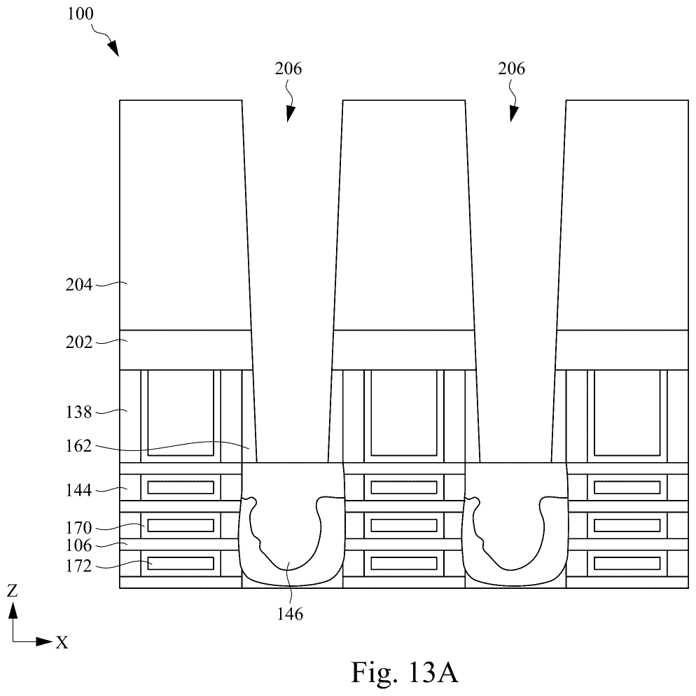

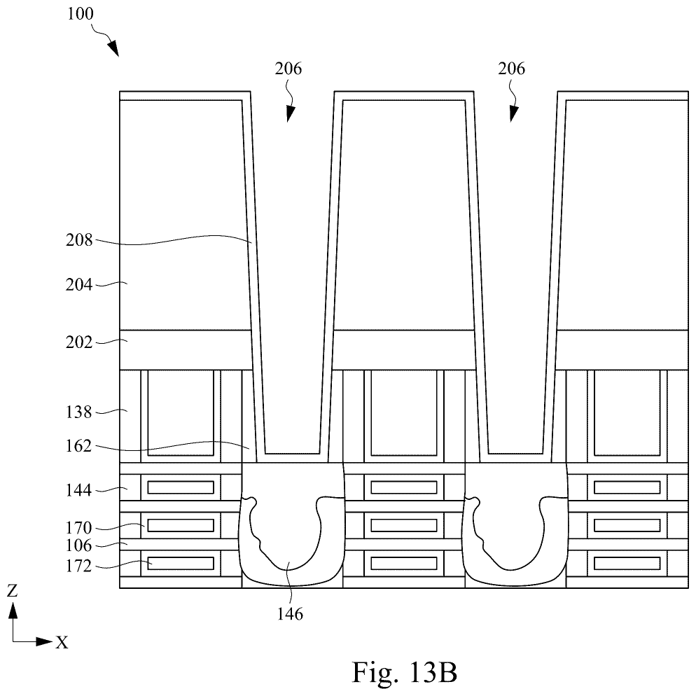

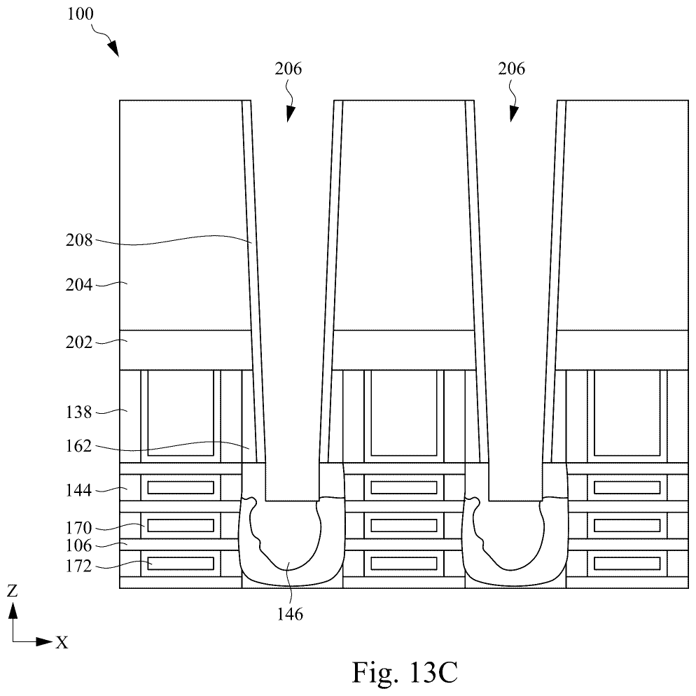

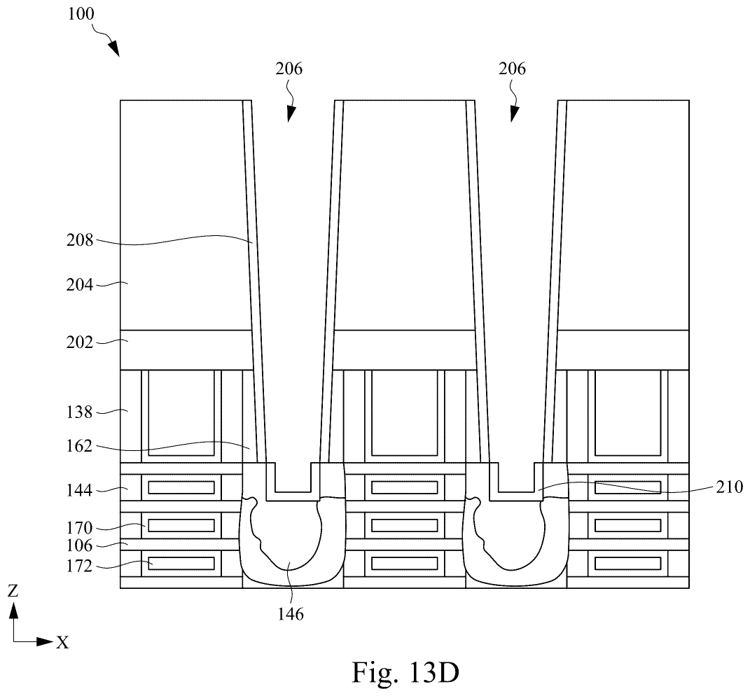

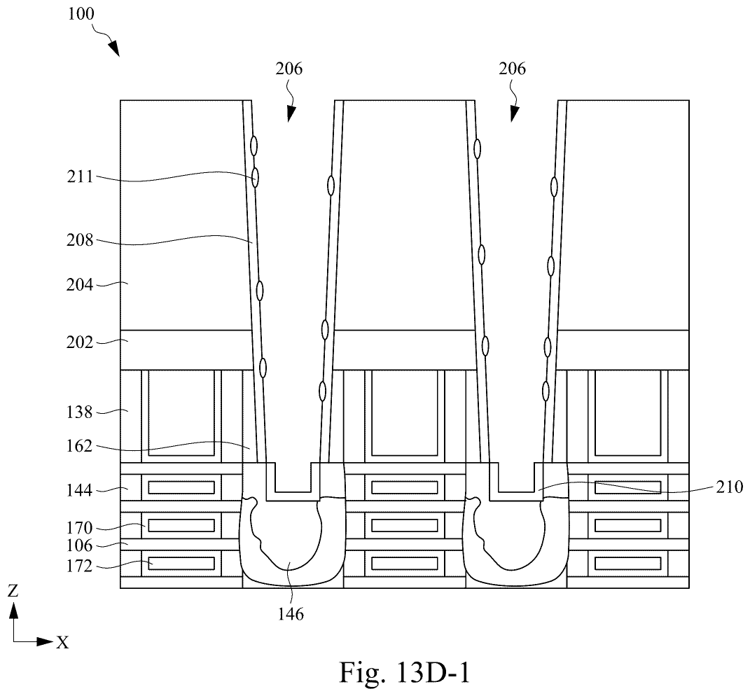

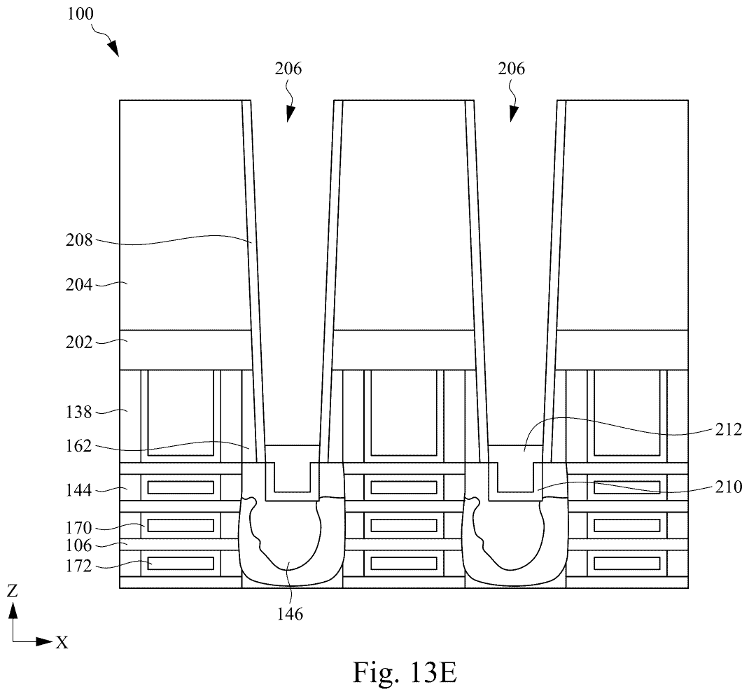

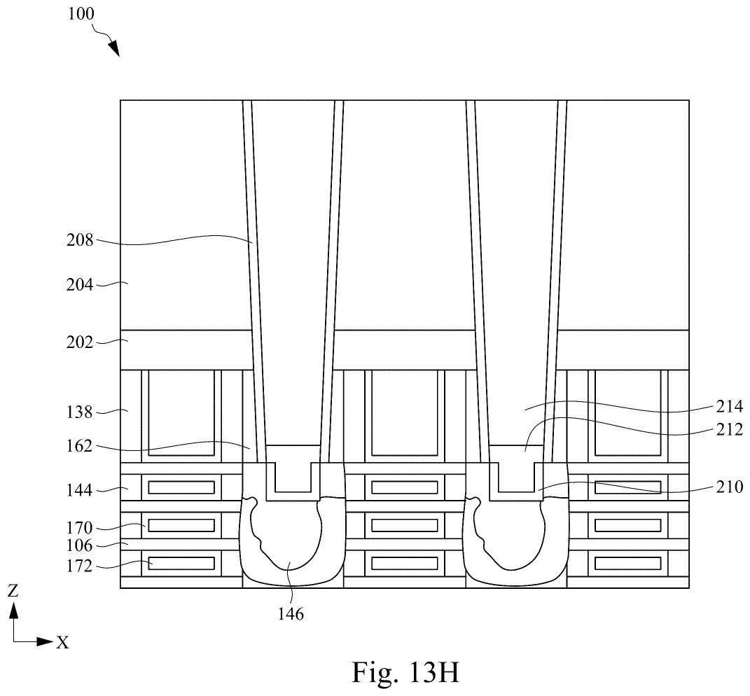

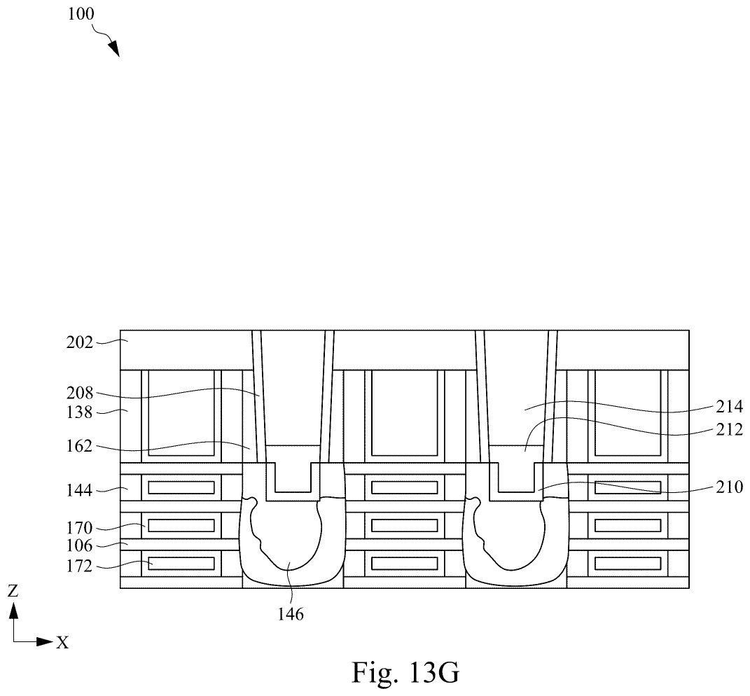

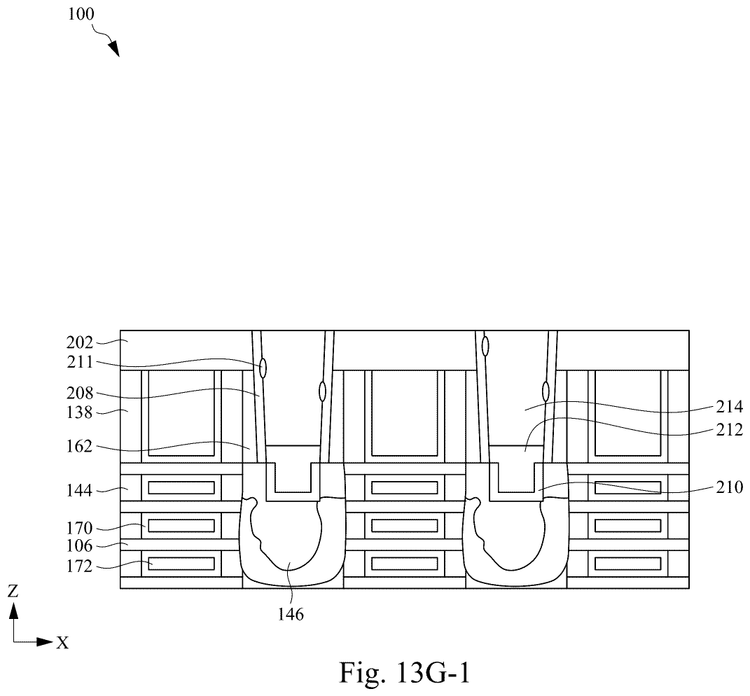

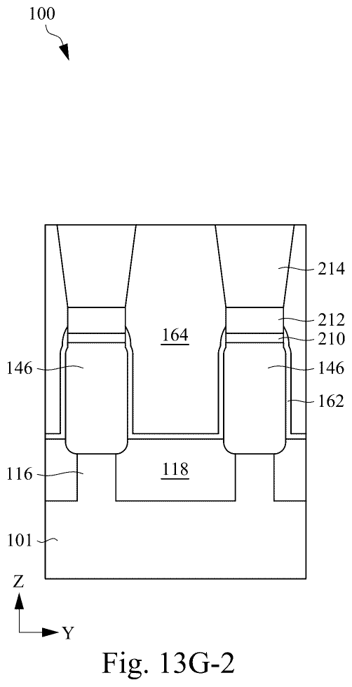

FIGS. 13A-13G are cross-sectional side views of various stages of manufacturing the semiconductor device structure 100 taken along line A-A of FIG. 6, in accordance with some embodiments. As shown in FIG. 13A, openings 206 are formed in the ILD layer 204, the etch stop layer 202, the ILD layer 164, and the CESL 162 to expose the S/D regions 146. The openings 206 may be formed by one or more etch processes, such as dry etch processes, wet etch processes or a combination thereof. Next, as shown in FIG. 13B, a dielectric layer 208 is formed on the exposed surfaces of the semiconductor device structure 100. The dielectric layer 208 may be a carbon-containing layer having a k value less than about 4, such as from about 2.5 to about 3.9. In some embodiments, the dielectric layer 208 includes or is made of SiOC or SiOCN. In some embodiments, the k value of the dielectric layer 208 is less than the k values of the CESL 162, the spacer 138, and the dielectric spacer 144. In some embodiments, in order to keep the carbon in the dielectric layer 208 during the subsequent processes, the dielectric layer 208 is formed using a cyclic CVD process. Furthermore, the cyclic CVD process can form a substantially conformal dielectric layer 208, as shown in FIG. 13B.

In some embodiments, the cyclic CVD process is a cyclic PECVD process including introducing a first precursor into the processing chamber in which the semiconductor device structure 100 is placed therein. The first precursor may include silicon and carbon. In some embodiments, the first precursor includes Si—C—Si bonds, such as Si—C—Si—(CH₃)₃. In some embodiments, the first precursor includes Si—CH₃ bonds, such as methylsilane. In some embodiments, the first precursor is introduced into the processing chamber, and a silicon and carbon containing plasma is formed in the processing chamber. The silicon and carbon containing species from the plasma bond with surfaces of the semiconductor device structure 100. Next, a purge process is performed to remove any first precursor not bonded to the surfaces of the semiconductor device structure 100 from the processing chamber. A second precursor is then introduced into the processing chamber. The second precursor may be an oxygen-containing precursor, and an oxygen-containing plasma is formed in the processing chamber. In some embodiments, the oxygen-containing precursor includes O₂ gas. In some embodiments, the oxygen-containing precursor also includes nitrogen, such as NO₂ gas. The oxygen-containing species from the oxygen-containing plasma reacts with the silicon and carbon containing species to form a first layer. In some embodiments, the first precursor is chosen so the first layer does not have a reaction site for the subsequent silicon and carbon containing species. For example, the plasma excited species of the first precursor (Si—C—Si—(CH₃)₃ or methylsilane) may react with the plasma excited species of the second precursor (O₂ gas or NO₂ gas) to form Si—C—Si—O, Si—C—O, Si—C—Si—NO, or Si—C—NO, and the first layer includes SiOC or SiOCN. The introducing of the first and second precursors into the processing chamber and the forming of the first layer is one cycle of the cyclic CVD process.

After another purge process to remove any second precursor not reacted with the first precursor from the processing chamber, the cycle is repeated. For example, the first precursor is introduced into the processing chamber, and a plasma is formed in the processing chamber. As described above, the first layer does not have reaction sites for the plasma excited species of the first precursor, and the plasma excited species of the first precursor are rested on the first layer by the van der Waals force. In some embodiments, in order to have sufficient amount of the plasma excited species of the first precursor on the first layer, the flow rate of the first precursor into the processing chamber may be high, such as from about 100 standard cubic centimeters per minute (sccm) to about 300 sccm. After another purge process, the second precursor is introduced into the processing chamber, a plasma is formed from the second precursor, and a second layer is formed on the first layer. The second layer may be formed in the same way as the first layer. However, the first and second layers are connected by van der Waals force. Compared to an ALD process, the layer formed by a cycle of the ALD process has reaction sites for the subsequently introduced precursor in the subsequent cycle of the ALD process, and the layers formed by the cycles are bonded by covalent bonds. In some embodiments, the distance between the first and second layers formed by the cyclic CVD process is greater than the distance between the layers formed by the ALD process. As a result, the resulting layer formed by the cyclic CVD process is porous and has a lower k value. In some embodiments, the dielectric layer 208 and the spacer 138 include the same material, such as SiOCN, but the k value of the dielectric layer 208 is less than the k value of the spacer 138 as a result of the more porous dielectric layer 208.

The cycle of cyclic CVD process is repeated one or more times to form additional layers, and the layers formed by the cyclic CVD process form the dielectric layer 208. In other words, the dielectric layer 208 includes multiple layers formed by the multiple cycles of the cyclic CVD process. The number of the cycles is based on the predetermined thickness of the dielectric layer 208. In some embodiments, the dielectric layer 208 has a thickness ranging from about 3 nm to about 5 nm, and the number of cycles ranges from about 300 to about 500. After the predetermined thickness of the dielectric layer 208 is reached, a treatment process is performed on the dielectric layer 208 to cross link some or all of the individual layers formed by the cycles of the cyclic CVD process. In some embodiments, the treatment process includes exposing the dielectric layer 208 to a hydrogen-containing plasma. As a result of the cross linking of the layers, more Si—C—Si bonds are formed. In some embodiments, the treatment process is performed for a time duration that all of the layers of the dielectric layer 208 are cross linked. As a result, the concentration of Si—C—Si is substantially constant throughout the dielectric layer 208. In some embodiments, the treatment process is performed for a time duration that some of the layers of the dielectric layer 208 are cross linked. As a result, the concentration of the Si—C—Si decreases in a direction from the surface of the dielectric layer 208 exposed in the opening 206 to the surface of the dielectric layer 208 adjacent the gate electrode layer 172, as shown in FIG. 13B. In some embodiments, the higher concentration of Si—C—Si leads to higher k value. Thus, in some embodiments, the k value of the dielectric layer 208 varies. For example, the k value of the dielectric layer 208 decreases in a direction from the surface of the dielectric layer 208 exposed in the opening 206 to the surface of the dielectric layer 208 adjacent the CESL 162.

As shown in FIG. 13C, portions of the dielectric layer 208 formed on the horizontal surfaces of the semiconductor device structure 100 are removed. In some embodiments, an anisotropic etch process is performed to remove the portions of the dielectric layer 208. Next, an ash process is performed to remove any byproducts formed during the anisotropic etch process. In some embodiments, the dielectric layer 208 is not formed by the cyclic CVD process and the treatment process described above, and the dielectric layer 208 includes a majority of Si—CH₃ bonds instead of a majority of Si—C—Si bonds. The ash process may remove the carbon from the Si—CH₃ bonds. However, the ash process does not remove the carbon from the Si—C—Si bonds. Thus, in some embodiments, as a result of the cyclic CVD process and the treatment process, the carbon concentration of the dielectric layer 208 is unaffected by the ash process.

After the ash process, the semiconductor device structure 100 may be transferred to another tool or processing chamber for subsequent processes, and the semiconductor device structure 100 may be exposed to air. As a result, the S/D regions 146 may be oxidized. For example, an oxide layer may be formed on the S/D region 146. In order to remove the oxide layer formed on the S/D regions 146, an etch process may be performed. The etch process may be any suitable etch process, such as a dry etch process, a wet etch process, or a combination thereof. In some embodiments, the dielectric layer 208 is not formed by the cyclic CVD process and the treatment process, the carbon in the dielectric layer 208 is removed by the ash process, and the etch process to remove the oxide layer also removes the dielectric layer 208. In some embodiments, the dielectric layer 208 is formed by the cyclic CVD process and the treatment process, and the carbon in the dielectric layer 208 is not affected by the ash process due to the Si—C—Si bonds, and the etch process to remove the oxidized portions of the S/D regions 146 does not substantially affect the dielectric layer 208. As a result, the dielectric layer 208 remains between the gate electrode layer 172 and the subsequently formed conductive feature 214 (FIG. 13H), and the low k value of the dielectric layer 208 can lead to reduced capacitance and improved alternating current (AC) performance.

As shown in FIG. 13D, silicide layers 210 are selectively formed on the S/D regions 146. In some embodiments, the silicide layer 210 is formed by selectively depositing a metal layer on the S/D region 146 and reacting with the S/D region 146. For example, a titanium layer may be selectively deposited on the S/D region 146 at a processing temperature of about 400 degrees Celsius, and the titanium layer reacts with the S/D region 146 to form a TiSi layer at the processing temperature. In some embodiments, the dielectric layer 208 is made of SiOC, and the metal layer does not form on the dielectric layer 208. For example, the metal layer is a titanium layer, and TiCl₄ is used as the precursor for forming the metal layer. TiCl₄ does not form on the oxide material of the dielectric layer 208. In some embodiments, the dielectric layer 208 is made of SiOCN, and a small amount of the metal layer 211 is formed on the dielectric layer 208, as shown in FIG. 13D-1. As shown in FIG. 13D-1, the metal layer 211 may be a discontinuous layer, and each segment of the metal layer 211 has a thickness ranging from about 0.5 nm to about 1 nm.

In some embodiments, there is an incubation delay on the dielectric layer 208 when forming the metal layer. For example, there is no growth of the metal layer on the dielectric layer 208 until the metal layer formed on the S/D region 146 reaches about 40 angstroms. Thus, in some embodiments, the thickness of the metal layer is less than about 40 angstroms to ensure that no metal layer is formed on the dielectric layer 208. As a result, in some embodiments, the silicide layer 210 has a thickness ranging from about 20 angstroms to about 40 angstroms.

In some embodiments, the dielectric layer 208 includes SiN, and the metal layer is also formed on the dielectric layer 208. For example, TiCl₄ forms on the nitride material of the dielectric layer 208 to form a titanium layer. As a result, an etch back process may be performed to remove the metal layer from the dielectric layer 208. The etch back process may damage the silicide layers 210. Thus, by forming the dielectric layer 208 with SiOC or SiOCN, damaging the silicide layers 210 is minimized.

As shown in FIG. 13E, a metal layer 212 is formed on the silicide layer 210 in a bottom-up fashion. In some embodiments, the metal layer 212 includes fluorine-free tungsten (FFW). After forming the metal layer 212, a clean process may be performed to remove any metal layer 212 that may have formed on the dielectric layer 208. The metal layer 211 (FIG. 13D-1) may be also removed by the clean process. The clean process may be any suitable clean process. In some embodiments, the clean process is a wet clean process using hot deionized water.

As shown in FIG. 13F, a conductive feature 214 is formed in the opening 206. The conductive feature 214 is electrically connected to the S/D region 146 via the silicide layer 210 and the metal layer 212. The conductive feature 214 may include any electrically conductive material, such as Ru, Mo, Co, Ir, W, Ti, Ta, Cu, TiN, TaN or combinations thereof, or other suitable material. The conductive feature 214 may be formed by any suitable process, such as PVD or ECP. Next, as shown in FIG. 13G, a planarization process, such as a CMP process, is performed to remove the ILD layer 204. As a result, as shown in FIG. 13G, the top surfaces of the conductive features 214 and the top surface of the etch stop layer 202 are substantially coplanar. As described above, in some embodiments, the dielectric layer 208 has a Si—C—Si concentration profile that decreases in a direction from the conductive feature 214 to the gate electrode layer 172.

FIG. 13G-1 illustrates an embodiment that the discontinuous metal layer 211 remains in the structure. In some embodiments, the metal layer 211 and the conductive feature 214 include different materials.

FIG. 13G-2 is a cross-sectional side view of one of various stages of manufacturing the semiconductor device structure 100 taken along line C-C of FIG. 6, in accordance with some embodiments. FIG. 13G-1 illustrates the semiconductor device structure 100 at the same manufacturing stage as the semiconductor device structure 100 shown in FIG. 13G. As shown in FIG. 13G-1, the conductive feature 214 is formed in the ILD layer 164. In some embodiments, the conductive feature 214 and the metal layer 212 include the same material, and the conductive feature 214 and the metal layer 212 are viewed as a single structure.

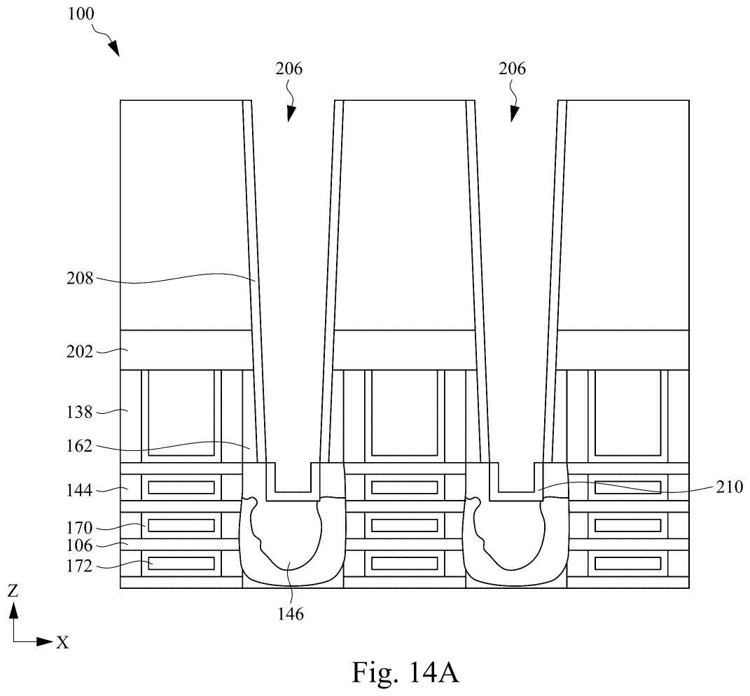

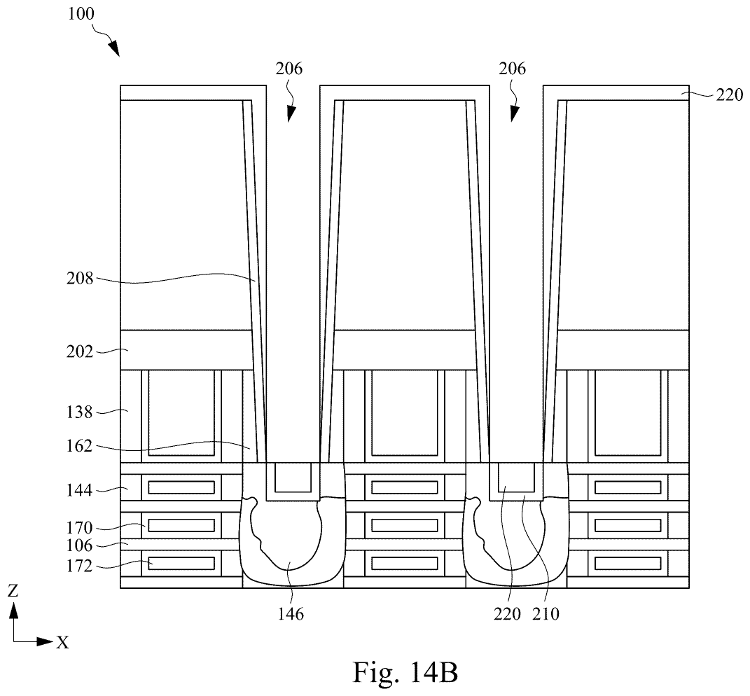

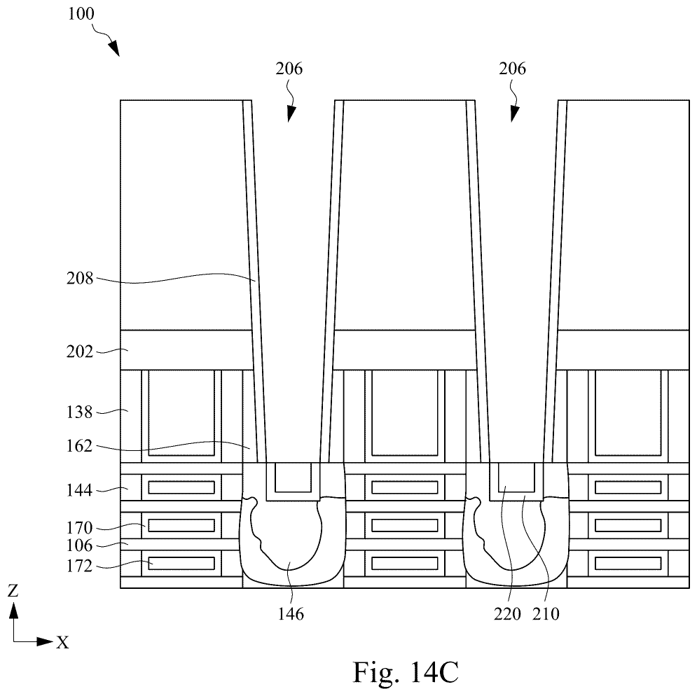

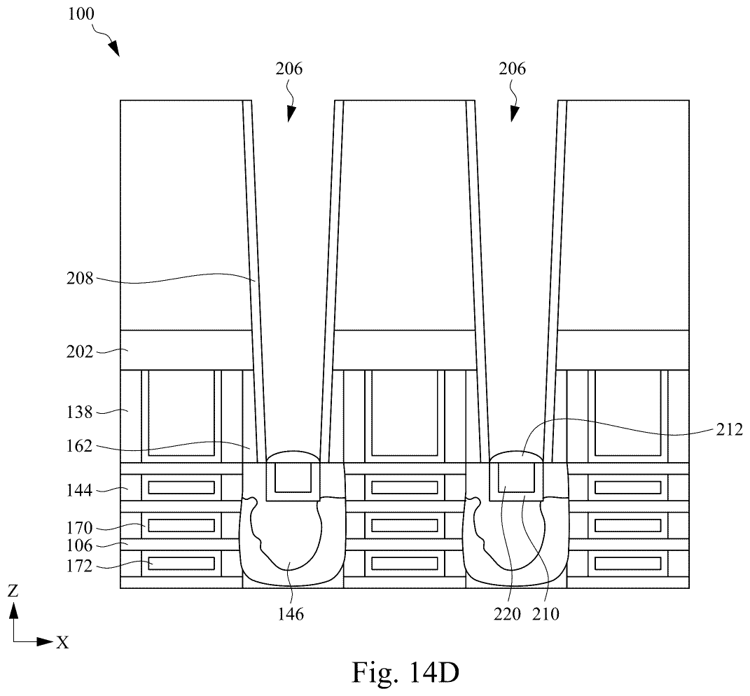

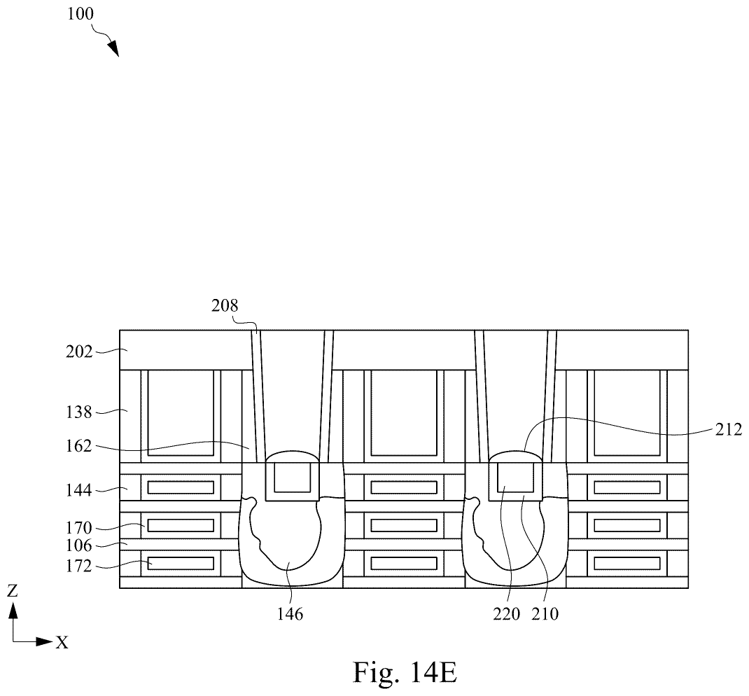

FIGS. 14A, 14B, 14C, 14D, and 14E are cross-sectional side views of various stages of manufacturing the semiconductor device structure 100 taken along line A-A of FIG. 6, in accordance with alternative embodiments. FIG. 14A illustrates the semiconductor device structure 100 at the same manufacturing stage as the semiconductor device structure 100 shown in FIG. 13D. As shown in FIG. 14A, the silicide layer 210 is selectively formed on the S/D region 146. Next, as shown in FIG. 14B, a metal layer 220 is formed on the silicide layer 210 and dielectric layer 208. In some embodiments, the metal layer 220 is formed by a PVD process, so the thickness of the portion of the metal layer 220 formed on the dielectric layer 208 is less than the thickness of the portions of the metal layer 220 formed on the silicide layer 210, as shown in FIG. 14B. The metal layer 220 may include any suitable material, such as W, Ru, Co, or Cu.

Next, as shown in FIG. 14C, an etch back process is performed to remove the portion of the metal layer 220 formed on the dielectric layer 208. The etch back process may be controlled so the portion of the metal layer 220 formed on the silicide layer 210 is not substantially affected. For example, the etch back process may be an isotropic etch process with a low bias power or no bias power. In some embodiments, the etch back process is a wet etch process that includes oxidizing agent and acid, and no bias power is applied.

As shown in FIG. 14D, the metal layer 212 is formed on the metal layer 220 and the silicide layer 210. In some embodiments, the silicide layer 210 is covered with the metal layer 220, and the metal layer 212 is not in contact with the silicide layer 210. In some embodiments, the metal layer 212 is selectively formed on the metal layer 220 and then grow laterally to be over the silicide layer 210. As a result, the thickness of the metal layer 212 may vary. For example, as shown in FIG. 14D, the thickness of the center portion of the metal layer 212 formed over the metal layer 220 may be greater than the thickness of the edge portion of the metal layer 212 formed over the silicide layer 210. Next, as shown in FIG. 14E, the conductive feature 214 is formed in the opening 206, and the planarization process is performed to remove the ILD layer 204.

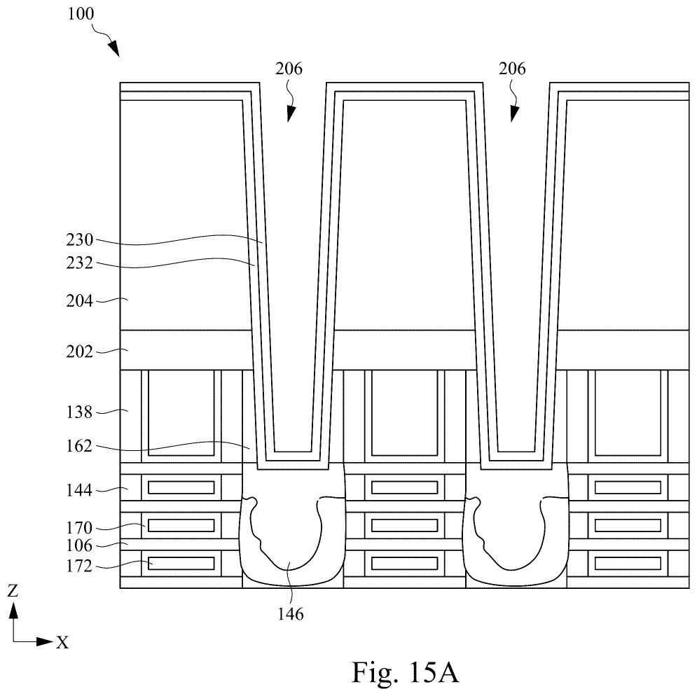

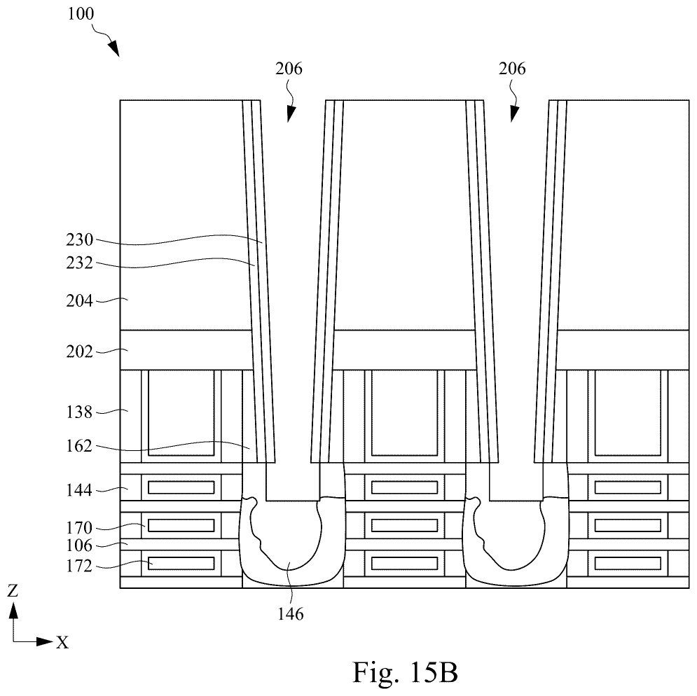

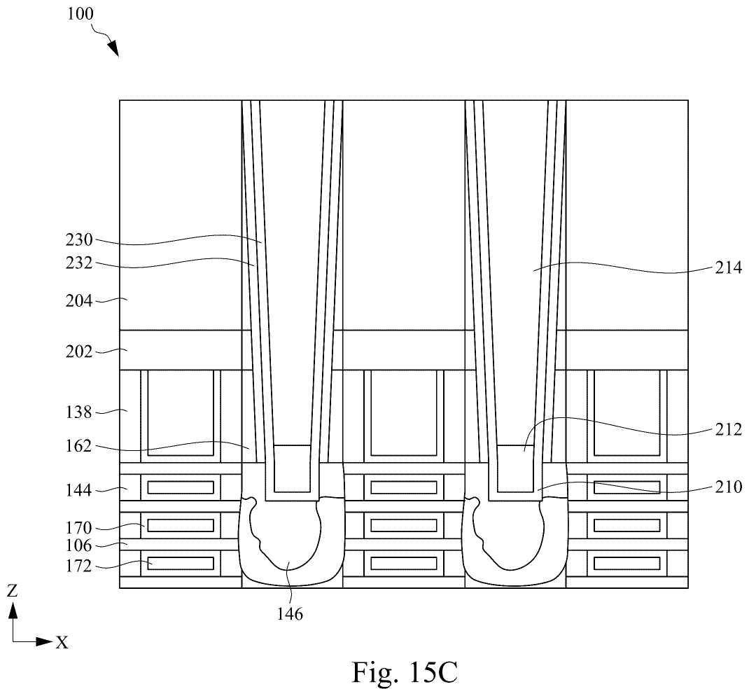

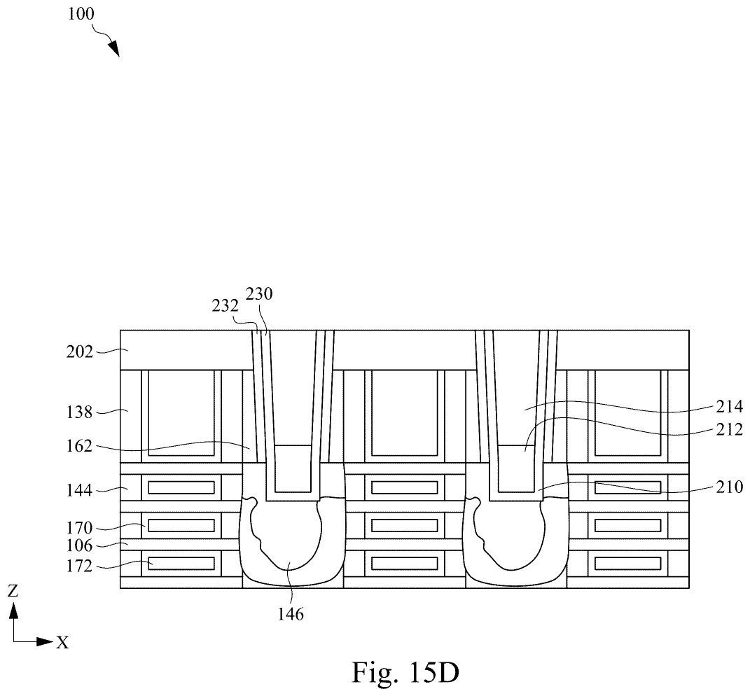

FIGS. 15A, 15B, 15C, and 15D are cross-sectional side views of various stages of manufacturing the semiconductor device structure 100 taken along line A-A of FIG. 6, in accordance with alternative embodiments. As shown in FIG. 15A, after forming the openings 206 in the ILD layer 204, the etch stop layer 202, the ILD layer 164, and the CESL 162, first and second dielectric layers 230, 232 are formed on the exposed surfaces of the semiconductor device structure 100. In some embodiments, the first dielectric layer 230 has a low k value, such as from about 2.5 to about 3.9, and the second dielectric layer 232 is made of a material that can withstand the subsequent ash and etch processes. In some embodiments, the first dielectric layer 230 includes the same material as the ILD layer 164. Thus, the first dielectric layer 230 has a low k value, but may be removed by the subsequent ash and etch processes. The second dielectric layer 232 protects the first dielectric layer 230 from the subsequent ash and etch processes, and the second dielectric layer 232 may have a higher k value than that of the first dielectric layer 230. In some embodiments, the second dielectric layer 232 is made of SiN. Even though the SiN layer is not affected by the subsequent ash and etch processes, the k value of the SiN layer is high, such as about 6.8. Furthermore, the metal layer to form the silicide layer 210 may be formed on the SiN layer. Thus, in some embodiments, the second dielectric layer 232 includes the same material as the dielectric layer 208 and is formed by the same process as the dielectric layer 208. In some embodiments, the first dielectric layer 230 has a thickness ranging from about 1 nm to about 2 nm, and the second dielectric layer 232 has a thickness ranging from about 2 nm to about 3.5 nm.

As shown in FIG. 15B, the portions of the first and second dielectric layers 230, 232 formed on horizontal surfaces are removed. In some embodiments, two anisotropic etch processes are performed to remove the portions of the dielectric layers 230, 232. For example, a first anisotropic etch process is performed to remove the portions of the second dielectric layer 232 formed on the horizontal surfaces, followed by a second anisotropic etch process to remove the portions of the first dielectric layer 230 formed on the horizontal surfaces. Next, an ash process is performed to remove any byproducts formed during the anisotropic etch processes, and an etch process is performed to remove the oxide layer formed on the S/D region 146. As described above, the second dielectric layer 232 is not affected by the ash and etch processes.

As shown in FIG. 15C, the silicide layer 210 is selectively formed on the S/D region 146, the metal layer 212 is formed on the silicide layer 210, and the conductive feature 214 is formed on the metal layer 212. In some embodiments, the metal layer 220 (FIG. 14C) is first formed on the silicide layer 210, and the metal layer 212 is formed on the metal layer 220. Next, as shown in FIG. 15D, the planarization process is performed to remove the ILD layer 204.

Embodiments of the present disclosure provide a semiconductor device structure 100 including a dielectric layer 208 made of a low k dielectric material, such as SiOC or SiOCN. Some embodiments may achieve advantages. For example, the dielectric layer 208 is disposed between the gate electrode layer 172 and the conductive feature 214, and the capacitance is reduced due to the low k value. Furthermore, the SiOC or SiOCN of the dielectric layer 208 can enable a selective deposition of the silicide layer 210, which reduces the risk of damaging the silicide layer 210 if the silicide layer 210 is not selectively formed.

An embodiment is a semiconductor device structure. The structure includes a gate electrode layer disposed over a semiconductor layer, a source/drain region disposed adjacent the semiconductor layer, an interlayer dielectric (ILD) layer disposed over the source/drain region, a conductive feature disposed in the ILD layer over the source/drain region, and a first dielectric layer disposed between the gate electrode layer and the conductive feature. The first dielectric layer has a Si—C—Si concentration profile that decreases in a direction from the conductive feature to the gate electrode layer.

Another embodiment is a semiconductor device structure. The structure includes a gate electrode layer disposed over a semiconductor layer, a source/drain region disposed adjacent the semiconductor layer, an interlayer dielectric (ILD) layer disposed over the source/drain region, a conductive feature disposed in the ILD layer over the source/drain region, a first dielectric layer disposed between the gate electrode layer and the conductive feature, a second dielectric layer distinct from the first dielectric layer disposed between the first dielectric layer and the gate electrode layer, a contact etch stop layer disposed between the second dielectric layer and the gate electrode layer, and a spacer disposed between the contact etch stop layer and the gate electrode layer.

A further embodiment is a method. The method includes forming a source/drain region, depositing a contact etch stop layer (CESL) over the source/drain region, depositing an interlayer dielectric (ILD) layer over the CESL, forming an opening in the ILD layer and the CESL to expose the source/drain region, and depositing a dielectric layer in the opening by a cyclic chemical vapor deposition process. The depositing of the dielectric layer includes depositing a first layer in the opening, depositing a second layer on the first layer, wherein the first and second layers are connected by van der Waals force, and performing a treatment process to cross link the first and second layers. The method further includes removing a portion of the dielectric layer to expose the source/drain region and selectively forming a silicide layer on the source/drain region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a gate electrode layer disposed over a semiconductor layer;
a source/drain region disposed adjacent the semiconductor layer;
an interlayer dielectric (ILD) layer disposed over the source/drain region;
a conductive feature disposed in the ILD layer over the source/drain region; and
a first dielectric layer disposed between the gate electrode layer and the conductive feature, wherein the first dielectric layer has a Si—C—Si concentration profile that decreases in a direction from the conductive feature to the gate electrode layer.

2. The semiconductor device structure of claim 1, further comprising a silicide layer disposed between the source/drain region and the conductive feature.

3. The semiconductor device structure of claim 2, further comprising a metal layer disposed between the silicide layer and the conductive feature.

4. The semiconductor device structure of claim 1, wherein the first dielectric layer comprises SiOC or SiOCN.

5. The semiconductor device structure of claim 4, wherein a k value of the first dielectric layer ranges from about 2.5 to about 3.9.

6. The semiconductor device structure of claim 1, further comprising a second dielectric layer disposed between the first dielectric layer and the gate electrode layer.

7. The semiconductor device structure of claim 6, wherein the first and second dielectric layers comprise different materials.

8. The semiconductor device structure of claim 7, wherein a k value of the first dielectric layer is higher than a k value of the second dielectric layer.

9. A semiconductor device structure, comprising:
a gate electrode layer disposed over a semiconductor layer;
a source/drain region disposed adjacent the semiconductor layer;
an interlayer dielectric (ILD) layer disposed over the source/drain region;
a conductive feature disposed in the ILD layer over the source/drain region;
a first dielectric layer disposed between the gate electrode layer and the conductive feature;
a second dielectric layer distinct from the first dielectric layer disposed between the first dielectric layer and the gate electrode layer;
a contact etch stop layer disposed between the second dielectric layer and the gate electrode layer; and
a spacer disposed between the contact etch stop layer and the gate electrode layer.

10. The semiconductor device structure of claim 9, wherein the first dielectric layer comprises SiN, SiOC, or SiOCN.

11. The semiconductor device structure of claim 10, wherein the second dielectric layer comprises silicon oxide.

12. The semiconductor device structure of claim 11, wherein a k value of the first dielectric layer is higher than a k value of the second dielectric layer.

13. The semiconductor device structure of claim 9, wherein the first and second dielectric layers and the contact etch stop layer are disposed over the source/drain region.

14. The semiconductor device structure of claim 13, wherein the spacer is disposed over the semiconductor layer.

15. A method, comprising:
forming a source/drain region;
depositing a contact etch stop layer (CESL) over the source/drain region;
depositing an interlayer dielectric (ILD) layer over the CESL;
forming an opening in the ILD layer and the CESL to expose the source/drain region;
depositing a dielectric layer in the opening by a cyclic chemical vapor deposition process, comprising:
depositing a first layer in the opening;
depositing a second layer on the first layer, wherein the first and second layers are connected by van der Waals force; and
performing a treatment process to cross link the first and second layers;
removing a portion of the dielectric layer to expose the source/drain region; and
selectively forming a silicide layer on the source/drain region.

16. The method of claim 15, wherein depositing the dielectric layer in the opening by the cyclic chemical vapor deposition process further comprises depositing a third layer on the second layer, wherein the second and third layer are connected by van der Waals force.

17. The method of claim 16, wherein the dielectric layer comprises the first, second, and third layers, and the first and second layers have a k value greater than a k value of the third layer.

18. The method of claim 16, wherein the treatment process cross links the first, second, and third layers.

19. The method of claim 15, further comprising performing an ash process after the removal of the portion of the dielectric layer and before the selectively forming of the silicide layer.

20. The method of claim 19, wherein selectively forming of the silicide layer comprises selectively forming a metal layer on the source/drain region and reacting the metal layer with the source/drain region.
